(19) United States
(12) Patent Application Publication
(10) Pub. No.: US 2008/0087112 A1
(43) Pub. Date: Apr. 17, 2008

(54) Senior Ultrasonic Miniature Air Gap Inspection Crawler

(75) Inventors: Paul C. Bagley, Middleburgh, NY (US); Richard Hatley, Convent Station, NJ (US); Kenneth J. Hatley, Madison, NJ (US); Robert M. Roney, Schoharie, NY (US)

Correspondence Address: SUTHERLAND ASBILL & BRENNAN LLP, 999 PEACHTREE STREET, N.E., ATLANTA, GA, 30309, US

(73) Assignee: GENERAL ELECTRIC COMPANY, Schenectady, NY (US)

(21) Appl. No.: 11/306,600

(22) Filed: Jan. 4, 2006

(51) Int. Cl. G01R 31/34

(52) U.S. Cl. 73/865.8; 322/99

(57) ABSTRACT

An air gap inspection device for a generator field or stator core. The inspection device may include first and second side drive modules and a center drive module disposed between the side drive modules. The first, the second, and the center drive modules may include a track for driving on the generator field or the stator core. The inspection device also may have a transverse assembly connected to the center drive module. The transverse assembly may include an ultrasonic module.

### TECHNICAL FIELD

The present invention relates generally to a miniature robotic device and more particularly relates to a miniature robotic device for performing in-situ ultrasonic inspections of a generator field.

### BACKGROUND OF THE INVENTION

The visual inspection of a generator field and stator should be performed on a periodic basis. Conventional generator/stator inspection and testing procedures typically require the complete disassembly of the stator and the removal of the generator field from the stator before any inspections or tests can be performed on the unit. The cost of the disassembly and the removal of the field, the time it takes for this process, and the dangers of field removal have led to the occasional omission of the generator and stator examinations from outage schedules.

In-situ inspections of generators have been performed employing poles, trolleys, and field turning techniques. These procedures have not accomplished the inspection task in a satisfactory manner.

Miniature air gap inspection crawlers are disclosed in commonly owned U.S. Pat. Nos. 5,650,579 and 6,100,711, the contents of which are hereby incorporated by reference. These crawlers are designed to pass through the radial air gap between the core iron and the retaining ring for in-situ inspection of the field and stator core.

Video cameras and other inspection tools attached to the crawler may be used to perform generator field and stator core inspections. For example, a high-resolution video camera provides the operator with a clear view of the stator core laminations, stator wedges, field wedges, and the in-board ends of the retaining rings. The device thus provides detection capability for loose stator wedges, vibration bar sparking, core lamination damage due to foreign objects, motoring and hot spots, field wedge arcing, and surface heating damage. Through the generator in-situ inspection, information is gathered on the condition of the generator that can help determine if field removal is necessary.

Although these known devices are adequate for visual inspection, these visual systems cannot detect internal defects such as cracks or pits in the field teeth. Rather, such cracks can only be found by ultrasonic inspection. Currently, however, the rotor must be pulled out of the stator before an ultrasonic inspection can be performed.

There is a desire therefore for a device and method to perform in-situ ultrasonic inspection of a generator stator and field. The device preferably should be sized to pass through the radial air gap.

### SUMMARY OF THE INVENTION

The present application thus describes an air gap inspection device for a generator field or stator core. The inspection device may include first and second side drive modules and a center drive module disposed between the side drive modules. The first, the second, and the center drive modules may include a track for driving on the generator field or the stator core. The inspection device also may have a transverse assembly connected to the center drive module. The transverse assembly may include an ultrasonic module.

The transverse assembly may include a mounting block. A transverse block may be maneuverable along the mounting block. The transverse assembly may include a screw thread for maneuvering the transverse block along the mounting block. The transverse block may include a number of connecting links and a number of swing arms attached to the ultrasonic module. The ultrasonic module may include an ultrasonic transducer or a number of ultrasonic transducers. The inspection device further may include a camera assembly positioned on the transverse assembly.

The present application further may describe an air gap inspection device for a generator field or stator core. The inspection device may include first and second side drive modules and a center drive module disposed between the side drive modules. A maneuverable transverse block may be connected to the center drive module. The inspection device also may include an ultrasonic module. The ultrasonic module may be positioned on the maneuverable transverse block via a number of swing arms.

The transverse block may include a number of connecting links attached to the ultrasonic module. The ultrasonic module may include an ultrasonic transducer or a number of ultrasonic transducers. The inspection device further may include a camera assembly positioned on the transverse assembly.

These and other features of the present application will become apparent to one of ordinary skill in the art upon review of the following detailed description when taken in conjunction with the drawings and the appended claims.

### BRIEF DESCRIPTION OF THE DRAWINGS

FIG. 1 is a simplified perspective sketch of the miniature air gap inspection crawler.

FIG. 2 is a top view of the inspection crawler.

FIG. 3 shows the crawler in its collapsed position and expanded position and the tilting motion of the inspection module.

FIG. 4 shows further details of the mechanism for tilting the inspection module.

FIG. 5 is a partial side cross sectional view showing drive motors in the inspection module.

FIG. 6 is a perspective view of the miniature air gap inspection crawler with an ultrasonic module as is described herein.

### DETAILED DESCRIPTION

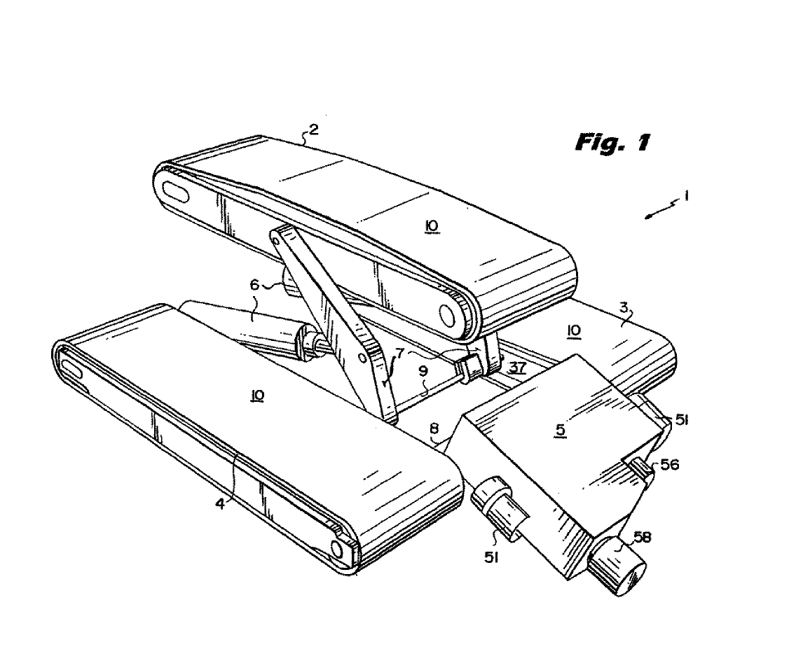

The miniature air gap inspection crawler 1 illustrated in a simplified form and in perspective in FIG. 1 includes three generally similar drive modules 2, 3 and 4. A pair of side drive modules 3 and 4 drive on the generator field through tracks 10. A center drive module 2 is adapted to drive on the stator core of the generator through its track 10. A pair of spring return pneumatic rams 6 pivotally attached to the side drive modules 3 and 4 permit the crawler to be expanded and collapsed by acting on a pair of link arms 7. A cross shaft 9 connects the link arms 7 together at one end and to the side drive modules 3 and 4 through a pair of yoke arms 37. At the other end the link arms 7 are connected to the center drive module 2. An inspection module 5, shown here as containing cameras 56 and 59 and with side mounted lights 51, is mounted at the front of the crawler 1 on a main yoke 8 that connects the two side drive modules. The inspection module 5 is mounted on the yoke 8 in a manner permitting it to be tilted such that the cameras may view the generator field.

The tracks 10 may include a flexible material and extend around the outside of the drive modules 2, 3 and 4 as shown. The inner sides of the tracks 10 may have teeth that engage teeth on the surface of the drive wheels and the idler wheels of the drive modules. The center drive module 2 and its track 10 are wider than the side drive modules 3 and 4 and their tracks 10. The wider center drive module track prevents the wide track 10 from dropping into a stator slot.

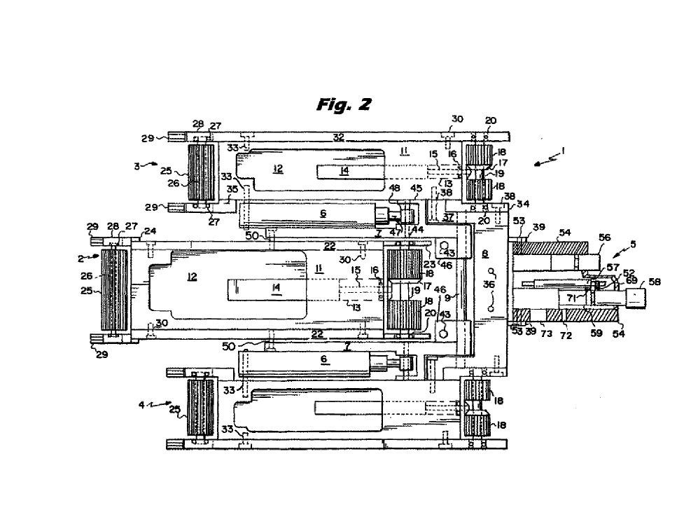

FIG. 2 is a top view of the crawler 1 illustrating the structural relationship and arrangement of the drive modules 2, 3 and 4, the ram 6—link arm 7 arrangement for raising the center drive module 2, the main yoke 8 and the inspection module 5. In this view of the crawler 1, the tracks 10 have been removed from the drive modules and the inspection module 5 is shown in cross section. The same numbers have been used to identify similar components of the crawler 1 and the drive modules 2, 3 and 4. Because the right side drive module 4 is a mirror image of the left side drive module 3 many of the numbers have been omitted from module 4 for purposes of clarity.

A drive module construction, with reference to the center drive module 2, includes a base plate 11 and side plates 22 secured to the base plate by bolts 30. Other attachment means may be used as one skilled in the art would appreciate. The base plate 11 includes a pocket, beneath 12, and a bore 13 for receiving the drive motor module 12, the motor 14, the drive shaft 15 and the bearing 16. The drive shaft 15 may be a unitary element or may include a shaft coupled to the motor output shaft in a conventional manner. A drive gear of a bevel gear assembly 17 is secured at the end of the drive shaft 15 in a driving relation to a bevel gear of the gear assembly 17 secured on the drive wheel shaft 19. The shaft 19 is mounted at its ends in a number of bearings 20 secured in forward side plates 23 that are integral extensions of the side plates 22. The two drive wheels 18 are mounted on the shaft 19 with the bevel gear assembly 17 in between. The drive wheels contain teeth on the circumferential surface for engaging the teeth on the underside of the track 10. At the rearward end of the drive module 2, an idler wheel 25 is supported on a shaft 26 held in a number of bearings 27 mounted in a number of slidable bearing blocks 28. The bearing blocks 28 are held in slots in a number of rear side plates 24 that are integral with the side plates 22. An adjustment screw 29 is used for sliding a bearing block 28 forwardly or rearwardly to provide for adjusting the location of the idler wheel 25 with respect to the base plate 11 and thus the tension on the track 10. An idler wheel 25 has a toothed surface as illustrated.

The side drive modules 3 and 4 are similar in construction to that of the center drive module 2 but differ in that they are not as wide and have only partial interior side plates, a plate 34 at the forward end and a plate 35 at the rearward end. In addition, the side drive modules 3 and 4 have pivot shafts 33 secured to the base plate 11 and side plates 32, and providing a pivot support for the pneumatic ram 6. The side plates 32 may include a single plate as shown. The idler wheel 25 is also adjustable by means of a number of screws 29 to provide for adjusting the tension on the track 10.

The two side drive modules 3 and 4 are secured at the interior side to the main yoke 8. In particular, the base plate 11 is secured to a yoke arm 37 by a bolt 38 and a forward side plate 34 is secured to the main yoke 8 by another bolt 38. A number of screws 36 in the main yoke 8 are for securing the inspection module yoke 60, illustrated in FIG. 4. A pair of struts 39 extends forwardly from the main yoke 8 for pivotally holding the inspection module 5. The struts 39 alternatively may include a U-shaped bracket secured to the front of main yoke 8.

The pneumatic rams 6 and the link arms 7 are assembled between the center drive module 2 and the side drive modules 3 and 4 in a manner that permits the center drive module 2 to be raised with respect to the side drive modules 3 and 4. Each link arm 7 includes a pin flange 45 and a clamping plate 46. The link arms 7, of the configuration illustrated, are secured to the center drive module side plates 22 by means of screws 50 in a manner that allows a link arm to pivot on the screw. At the forward end of the link arms 7, clamp plates and clamping bolts 43 clamp the link arms to the cross shaft 9. The ends of the cross shaft 9 are disposed in bores of yoke arms 37 in a manner that permits the cross shaft 9 to rotate. Clamping the link arms 7 to the cross shaft 9 ensures that the center drive module 2 is kept from becoming skewed while being raised to the elevated position. A piston rod 47 of the pneumatic ram 6 is connected to the link pin 44 of the link arm 7 by a coupling 48. A link pin 44 is secured between the link arm 7 and the pin flange 45.

The inspection module 5, as shown in FIG. 2, contains a forward view camera 56 of fixed focus, a side view camera 59 that is remotely focused, a rotating prism 58 and a drive motor 57 stacked over a focus drive motor 70. A gear 69 on the drive shaft of motor 57 rotates the prism 58. A gear 71 is on the drive shaft of the motor 70 and drives the focus adjust mechanism of the camera 59. Side wall members 54 are the side walls of the inspection housing and receive pivot pins 53 which permit the module 5 to tilt in a downward direction. The side wall member 52 is the front wall of the inspection module housing. An element 73 is the opening for an electrical connector and an element 72 is an opening for a pneumatic air line connector. The lights 51 as illustrated in FIG. 1, but not shown in FIG. 2, are attached to the side wall members 54.

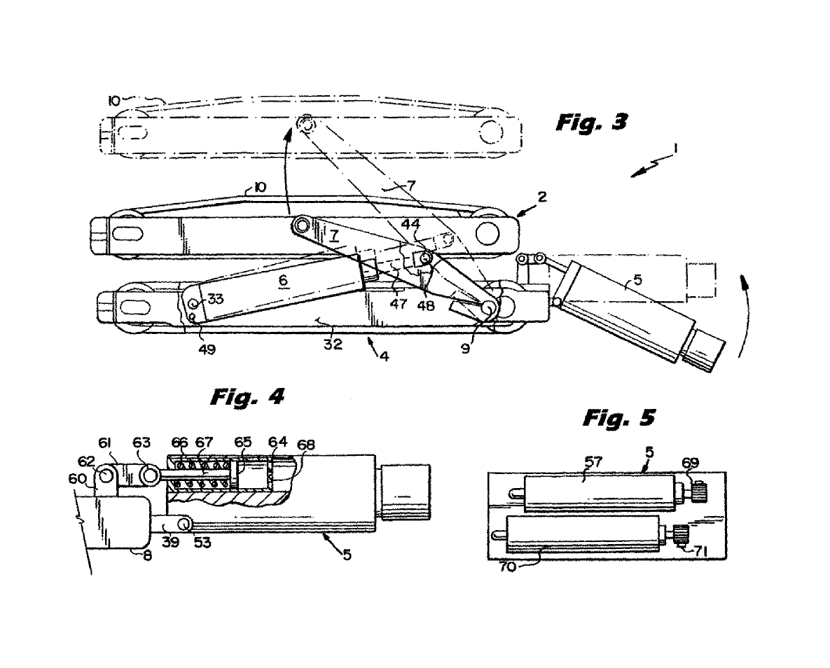

The pneumatic rams 6 are of the spring return type and are operated by air supplied through pneumatic lines (not shown) attached to an air inlet port 49 shown in FIG. 3. As further illustrated in FIG. 3, a piston rod 47 of the pressurized rams 6 acts on a link arm 7 via a coupling 48 and a link pin 44 to raise the center drive module 2 to an elevated position, shown in dotted lines, where its track 10 contacts and presses against the inside diameter of the stator core. The dotted link arm 7 is illustrated as being elongated but this is only to facilitate the showing of the raising of the center drive module 2. In FIG. 3, the side drive module 4 is cut away to show the right ram 6 and the link arm 7. The link arm 7 is cut away at the center to illustrate the coupling 48. Once the center drive module is raised to the elevated position, sufficient air pressure is supplied and maintained to the pneumatic rams 6 to force the side drive modules 3 and 4 against the generator field and the center drive module 2 against the stator core to hold the crawler 1 in place, even at a vertical, 90 or 270 degree, position and an inverted, 180 degree, position in the generator air gap. Return springs (not shown) of the spring return pneumatic rams 6 provide the crawler 1 with the capability of being collapsed in the event of a failure. By simply removing the supply of air to the pneumatic rams 6, the drive module 2 retracts from its elevated position, and the crawler 1 in its collapsed position is easily retrieved from a generator air gap.

Each of the motors 14 in the drive modules is a reversible servo motor individually controlled at a computer control console. The motors have the capability of driving the crawler at speeds of up to about 30 inches per minute. The speed of each motor 14 is controlled through a motion control program at the computer console.

To ensure accurate tracking in an axial run where the crawler 1 travels in the axial direction along the air gap of a generator, the crawler 1 is expanded and the center drive module 2 is in contact with the stator core and is driven at the same speed and in the opposite rotational direction to the side drive modules 3 and 4. When the crawler 1 is running in a circumferential direction, the crawler 1 is expanded and the center drive module 2 is in contact with the stator core and is driven slightly faster and in the opposite rotational direction to the side drive modules 3 and 4 in contact with the field in order to compensate for the greater diameter of the stator core. In order to turn the crawler 1, the speed between the left and the right side drive modules 3 and 4 is varied by driving the two modules at the same speed but in opposite directions that causes the crawler 1 to pivot about the contact point of the center core-contacting module. While the field side drive module tracks 10 are turning in opposite directions to turn the expanded crawler 10, the center core-contacting module track 10 can be oscillated forward and backward to reduce friction in making the turn.

As clearly illustrated in FIG. 4, the camera module 5 is supported on each side by a strut 39 and a pivot pin 53. A spring 66 of a spring return pneumatic air ram 64 keeps the module 5 in a generally horizontal position through its action on a piston 65, a piston rod 67, a pivot coupling 63, a link 61, a shaft 62 and an inspection module yoke 60. The application of air at an air inlet 68 moves the piston 65 against the spring 66, compressing it, which permits the module 5 to tilt downwardly with respect to the axis of the main yoke 8 by pivoting on the pins 53. Control of the air pressure can control the degree of the tilt. The controlled tilting capability of the inspection module 5 makes for improved viewing when the crawler 1 is moving in the circumferential direction in a generator air gap.

The camera 56 may be a high resolution, ⅓ inch, color CCD forward view camera with a field of view of approximately 50 degrees and a fixed focus for straight ahead viewing. The camera 56 is used both for navigating the crawler 1 through an air gap and making inspections. The camera 59 is a side view camera with the prism 58 that rotates 360 degrees and is primarily used for detailed inspection of the stator core, generator field and retaining ring faces. The camera 59 has a remotely controlled power focus and, in the preferred embodiment, is a high resolution, ⅓ inch, color CCD camera with a field of view of approximately 30 degrees. Rotation of the prism 58 and the focus of the camera 59 are by remote control of the motors 57 and 70, respectively, at the computer control console.

FIG. 5 illustrates the stacked electrical motors 57 and 70 in the inspection module 5. The upper motor 57 is coupled via a gear 69 to rotate the prism 58. The lower motor 70 drives the focus mechanism of camera 59 via its gear 71.

Prior to performing an inspection, the crawler 1 is compressed to its collapsed position as illustrated by the solid lines in FIG. 3. In this position the unit is about 1.1 inches high, 9.5 inches long and 8.5 inches wide. The camera module is about 0.9 inches high, 3 inches long and 2.5 inches wide. Other dimensions may be used herein. As shown in FIG. 2, the center module 2 extends to the rear of the crawler 1 and the camera module 5 is positioned forwardly.

An umbilical, which includes electrical cables, pneumatic lines and a tether line, is attached to the crawler. The electrical lines are connected to a computerized motion control system for control of the crawler 1 as one skilled in the art of motion control understands.

The crawler 1 in its collapsed position is inserted in a generator air gap at the 12 o'clock position and driven in a largely axial direction to a desired location, using the view from camera 56 as a navigation aid. Upon reaching a desired location in the air gap, the crawler 1 is expanded by supplying air through the attached air lines to the pneumatic rams 6. The spring return pneumatic rams 6 are of the same construction as the ram 64. The computer motion control system is used by an inspector to drive the crawler 1 to the necessary inspection points while the supply of air to the pneumatic ram 64 through an attached air line can be controlled to achieve a desired tilt of the inspection module 5.

The crawler 1 is normally retrieved from the generator air gap by driving it out. However, in the event of a motor failure, power failure or other situation that causes the crawler 1 to become immobile, the crawler 1 can easily be retrieved manually. Air pressure to the spring return pneumatic rams 6 is released and after the crawler 1 collapses to its collapsed position it is pulled out by the tether line.

The miniature air gap inspection crawler 1 permits inspection of the generator field and stator core with minimal disassembly of the generator, single ended entry into the generator and no rotation of the generator field. The views provided by the cameras allow a trained inspector to determine easily the maintenance procedures that need to be instituted and can be used to provide a history of the generator.

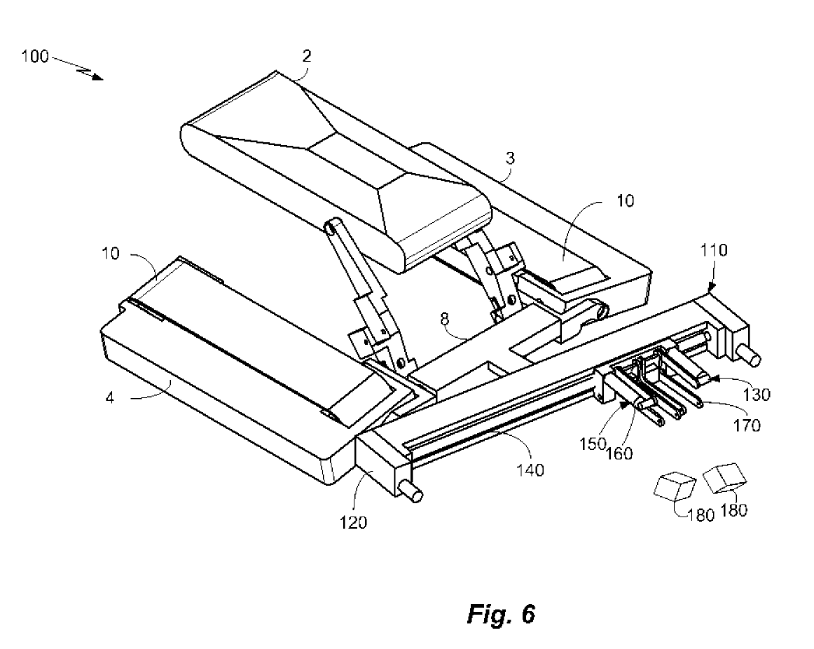

A further embodiment, a crawler 100, is shown in FIG. 6. Instead of the inspection module 5, a traverse assembly 110 is attached to the yoke 8. The traverse assembly 110 may be connected to the yoke 8 via a mounting block 120. The mounting block 120 may have any desired size or shape. Positioned on the mounting block 120 may be a traverse block 130. The traverse block 130 may be maneuverable along the horizontal direction via a traverse screw thread 140. A servo or a stepper motor or similar types of devices may power the screw thread 140. The traverse block 130 may have a pair of mounting arms 150 positioned thereon. Also positioned on the traverse block 130 may be a pair of connecting links 160. The connecting links 160 may secure an inspection device to the traverse block 130 as will be described in more detail below. The traverse block 130 also may have a number of swing arms 170. In this example, four (4) swing arms 170 are used, although any number may be used. The swing arms 170 permit movement of the inspection device at an angle along the vertical plane. The swing arms 170 may be powered via a pneumatic cylinder, a motor, or similar types of devices.

FIG. 6 shows the crawler 100 with a pair of ultrasonic transducers 180 that may be positioned within the connecting links 160 and the swing arms 170 of the traverse assembly 110. The transducers 180 may be of conventional design. The transducers 180, or any type of inspection device, may be maneuvered in the horizontal direction via the screw thread 140. The transducers 180 also may be maneuvered in the vertical direction via the swing arms 170. The transducers 180 may detect cracks as small as 0.025 inches (about 0.635 millimeters). The crawler 100 also may have means for spreading couplant before the transducers 180 and/or a means to vacuum the couplant after use. The couplant can be any desired fluid, including water. Any other types of inspection means may be used herein.

The crawler 100 also may have the cameras 56, 59 or similar types of camera modules positioned thereon. The cameras may be any conventional type of video device. Other types of monitoring or detection devices also may be mounted onto the crawler 100.

In use, the crawler 100 may be positioned within the radial air gap for introduction to the field as is described above. The crawler 100 thus has full access to all areas of the field. The crawler 100 can be maneuvered in any desired pattern so as to provide ultrasonic and other types of inspections. Alternatively, the crawler 100 may be maneuvered directly to an area of suspected damage.

It should be apparent that the foregoing relates only to the preferred embodiments of the present invention and that numerous changes and modifications may be made herein by one of ordinary skill in the art without departing from the general spirit and scope of the invention as defined by the following claims and the equivalents thereof.

What is claimed is:

1. An air gap inspection device for a generator field or stator core, comprising:
a first and a second side drive modules;
a center drive module disposed between the side drive modules;
the first, the second, and the center drive modules comprising a track for driving on the generator field or the stator core; and
a transverse assembly connected to the center drive module; the transverse assembly comprising an ultrasonic module.

2. The air gap inspection device of claim 1, wherein the transverse assembly comprises a mounting block.

3. The air gap inspection device of claim 2, wherein the transverse assembly comprises a transverse block maneuverable along the mounting block.

4. The air gap inspection device of claim 3, wherein the transverse assembly comprises a screw thread for maneuvering the transverse block along the mounting block.

5. The air gap inspection device of claim 1, wherein the transverse assembly comprises a maneuverable transverse block.

6. The air gap inspection device of claim 5, wherein the transverse block comprises a plurality of connecting links attached to the ultrasonic module.

7. The air gap inspection device of claim 5, wherein the transverse block comprises a plurality of swing arms attached to the ultrasonic module.

8. The air gap inspection device of claim 1, wherein the ultrasonic module comprises an ultrasonic transducer.

9. The air gap inspection device of claim 8, wherein the ultrasonic transducer comprises a plurality of ultrasonic transducers.

10. The air gap inspection device of claim 1, further comprising a camera assembly positioned on the transverse assembly.

11. An air gap inspection device for a generator field or stator core, comprising:
a first and a second side drive modules;
a center drive module disposed between the side drive modules;
a maneuverable transverse block connected to the center drive module; and
an ultrasonic module;
the ultrasonic module positioned on the maneuverable transverse block via a plurality of swing arms.

12. The air gap inspection device of claim 11, wherein the transverse block comprises a plurality of connecting links attached to the ultrasonic module.

13. The air gap inspection device of claim 11, wherein the ultrasonic module comprises an ultrasonic transducer.

14. The air gap inspection device of claim 13, wherein the ultrasonic transducer comprises a plurality of ultrasonic transducers.

15. The air gap inspection device of claim 11, further comprising a camera assembly positioned on the transverse assembly.
